(19) United States
(12) Patent Application Publication
(10) Pub. No.: US 2014/0283898 A1
(43) Pub. Date: Sep. 25, 2014

(54) Non-Planar Photovoltaic Device

(71) Applicants: Eric Pilat, Brison-Saint-Innocent (FR); Alexandre Vachez, Barberaz (FR)

(72) Inventors: Eric Pilat, Brison-Saint-Innocent (FR); Alexandre Vachez, Barberaz (FR)

(73) Assignee: Commissariat a L'Energie Atomique et aux Energies Alternatives, Paris (FR)

(21) Appl. No.: 14/342,092

(22) PCT Filed: Aug. 31, 2012
(86) PCT No.: PCT/EP2012/066968

§ 371 Date: Apr. 24, 2014

(30) Foreign Application Priority Data
Sep. 2, 2011 (FR) 1157786

(51) Int. Cl. H01L 31/042; H01L 31/18

(52) U.S. Cl. CPC H01L 31/0424; H01L 31/18
USPC 136/251; 438/66

(57) ABSTRACT

Process for manufacturing a photovoltaic device, characterised in that it comprises the following steps:
assembling at least one photovoltaic cell (12) to a flexible substrate (20); then,
producing notches (17) in the at least one photovoltaic cell in order to give it flexibility and allow the photovoltaic device to be deformed.

The invention relates to a process for manufacturing a photovoltaic device and to a photovoltaic device as such.

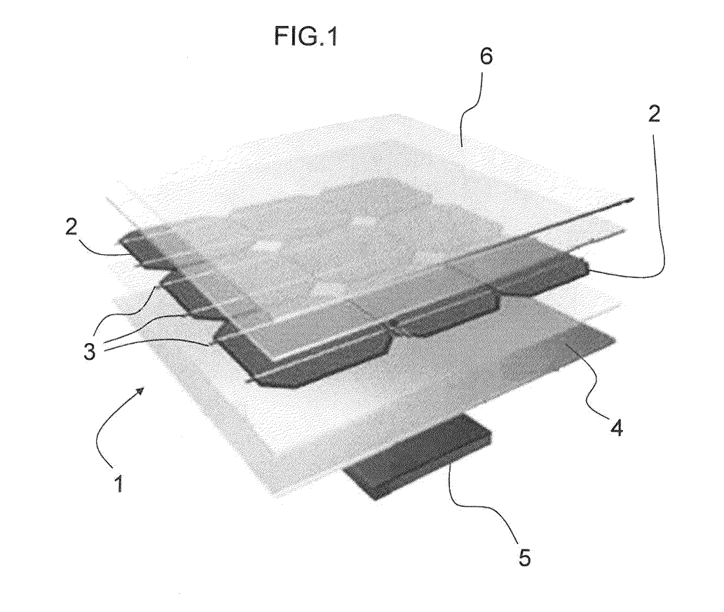

FIG. 1 illustrates a photovoltaic module 1 according to the prior art, it takes the form of a large square slab measuring between 1 and 3 metres per side, comprising a plurality of photovoltaic cells 2 that are connected together, and the surface electrical conductors 3 of which are connected together, for example by soldering, in order, finally, to conduct the current generated by all the photovoltaic cells 2 to a junction box 5 located under the module, which serves to electrically connect it to other modules. In addition, the photovoltaic cells 2 are covered with a protective glass glazing 6, on the upper surface of the module. Lastly, the lower side of the photovoltaic cells 2 is protected by a polymer laminate 4.

The use of photovoltaic modules 1 such as described above is very widespread and their format is almost standardised. However, there are particular implementations, such as when installed on the roof of a building in order to produce electricity to meet some of the needs of the building, for which the size and/or shape described above are/is not optimal. To improve integration of photovoltaic devices into roofs, it is known to manufacture smaller photovoltaic devices having the same structure as that described with reference to FIG. 1, these devices taking the form of flat tiles that can be placed on a roof, as replacements for existing tiles, using the same construction techniques. However, these existing solutions remain unsatisfactory because they are complicated and expensive to manufacture. in addition, they cannot be used to meet every aesthetic architectural requirement, and in particular cannot be used to replace curved tiles, such as Roman tiles, which are very commonplace. More generally, standard photovoltaic devices cannot be implemented on curved surfaces, thereby limiting the extent of their use.

Thus, there is a need for a solution allowing the aforementioned drawbacks to be remedied, and an object of the invention is in particular to provide a photovoltaic device that is suitable for a curved surface.

For this purpose, the invention is based on a process for manufacturing a photovoltaic device, characterised in that it comprises the following steps:
assembling at least one photovoltaic cell to a flexible substrate; then,
producing notches in the at least one photovoltaic cell in order to give it flexibility and allow the photovoltaic device to be deformed.

The process for manufacturing a photovoltaic device may comprise the following initial steps:
producing grooves in the flexible substrate; and
forming electrical conductors in these grooves.

The electrical conductors may be produced in the grooves by metal deposition in an electrochemical bath.

The notches may be produced in the at least one photovoltaic cell by laser etching.

The assembly of at least one photovoltaic cell to a flexible substrate may be obtained by polymerisation, cross-linking, welding, or adhesive bonding.

The process for manufacturing a photovoltaic device may comprise an additional step consisting in shaping the photovoltaic device into a non-planar shape.

The process for manufacturing a photovoltaic device may comprise an additional step consisting in adding a transparent resin-type protective layer to the photovoltaic device.

The invention also relates to a photovoltaic device, characterised in that it comprises at least one photovoltaic cell containing notches, which photovoltaic cell is assembled to a flexible substrate in order to form an assembly that is flexible and/or of non-planar shape.

The flexible substrate may comprise grooves containing conductors that do not occupy the entire height of the grooves, and the grooves may also contain conductors of photovoltaic cells, making contact with the conductors of the flexible substrate.

The flexible substrate may comprise a lower layer taking the form of a film and a polymer resin layer, and the grooves may extend through all or part of the thickness of the resin layer.

The grooves may be arranged in such a way as to superpose on the conductors protruding from the surface of the at least one photovoltaic cell so that these conductors are all housed in the grooves of the flexible substrate.

The notches may occupy all or part of the thickness of a photovoltaic cell and/or the thickness of a photovoltaic cell plus the thickness of the flexible substrate may be smaller than or equal to 250 μm, or smaller than or equal to 200 μm, and/or the photovoltaic device may have a non-planar shape comprising at least one curvature having a radius of curvature smaller than or equal to 1 metre.

The device for covering a roof may comprise an assemblage of photovoltaic devices such as described above, taking the form of tiles having a rounded and/or curved and/or cambered surface.

The invention also relates to a fabric, characterised in that it comprises photovoltaic devices such as described above.

The invention also relates to an automotive vehicle, characterised in that it comprises photovoltaic devices such as described above on its surface.

These objects, features and advantages of the present invention will be described in detail in the following description of a particular embodiment given by way of nonlimiting example and with regard to the appended figures, in which:

FIG. 1 shows an exploded perspective view of the structure of a photovoltaic module according to the prior art

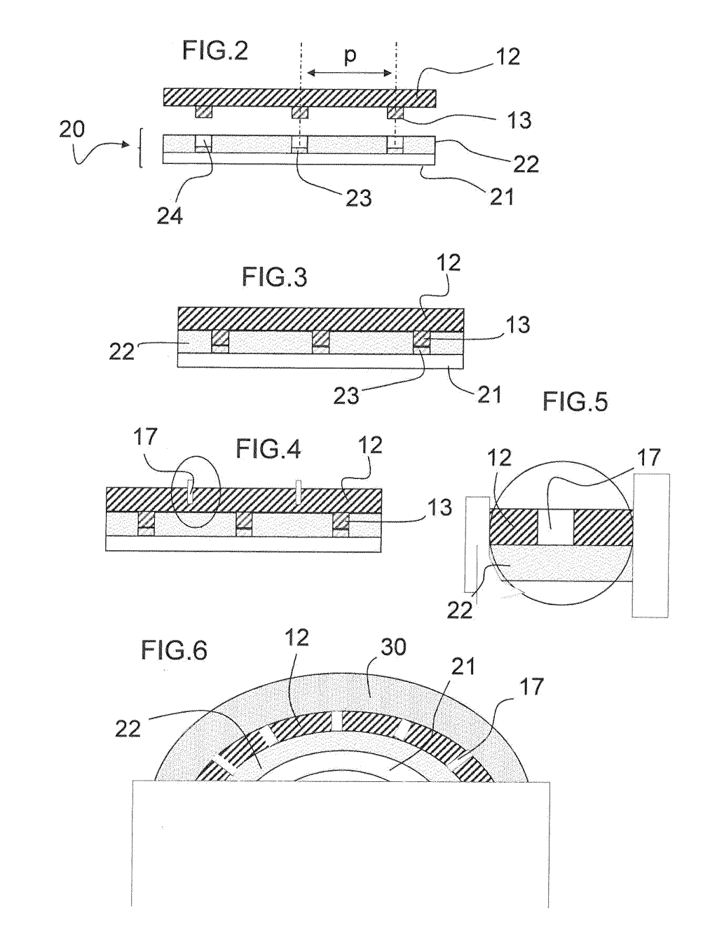

FIG. 2 schematically shows a first step of the manufacturing process of a photovoltaic device according to one embodiment of the invention.

FIG. 3 schematically shows a second step of the manufacturing process of a photovoltaic device according to the embodiment of the invention.

FIG. 4 schematically shows a third step of the manufacturing process of a photovoltaic device according to the embodiment of the invention.

FIG. 5 shows an enlargement of part of the photovoltaic device at the end of the third step according to the embodiment of the invention.

FIG. 6 schematically shows a photovoltaic device according to one embodiment of the invention.

Thus, FIG. 2 shows a first step of the manufacturing process of a photovoltaic device according to one embodiment of the invention. This process first comprises the manufacture of a silicon-based photovoltaic cell 12 or array of photovoltaic cells 12 using a prior-art process. Conductors 13 are arranged on a surface of this for these) cell(s) in order to conduct the current generated via a photovoltaic effect. They therefore protrude from the flat surface of this (or these) cell(s).

According to an essential element of the invention, the process comprises a step of manufacturing a flexible substrate 20 that is intended to receive one or more photovoltaic cells 12. In this embodiment, this flexible substrate 20 comprises a polymer multilayer structure: in the embodiment illustrated, it comprises a film 21 in its lower part, and a resin layer 22 in its upper part. This resin layer 22 contains grooves 24 through its thickness, in which grooves metal conductors 23 are arranged, a metal strip being placed therein or a metal ink being deposited by inkjet printing, or by electrodeposition using masks to deposit the metallisation in the grooves specifically, or by any other metal deposition solution, for example. In this embodiment, the grooves 24 extend right through the thickness of the resin layer 22 and therefore from the upper surface of the film 21. The conductors 23 occupy only part of the height of the grooves 24, leaving their upper part free to receive the conductors 13 of the photovoltaic cells. For this reason, the geometry of the grooves 24 corresponds to that of the conductors 13 of the photovoltaic cells 12 To facilitate this correspondence, the conductors 13 of the photovoltaic cells are rectilinear, parallel and arranged at a constant pitch p. They may also have a spherical shape that is simpler to produce (natural coalescence of alloys, making self-centring of the cell on the substrate possible, and thereby allowing very precise positioning).

FIG. 3 illustrates the result of the assembly of a photovoltaic cell 12 to the flexible substrate 20 Thus, it may be seen that the conductors 13 of the photovoltaic cell 12 make contact with the conductors 23 in the grooves 24 to form a single conductor occupying the entire height of the grooves. The flexible substrate 20 and the at least one photovoltaic cell 12 are then fastened by any means, such as by a polymerisation that causes them to bond adhesively, or by cross-linking, etc., in order to weld or adhesively bond the two elements.

Next, the manufacturing process comprises a step of producing notches 17, extending through all or part of the thickness of the photovoltaic cells 12, as illustrated in FIGS. 4 and 5, to form a network of notches 17 that are provided to allow the photovoltaic device to be subsequently folded in order to shape it into a desired three-dimensional shape. For this reason, the network of notches 17 is calculated beforehand using techniques of the type used in origami, in order to obtain whatever three-dimensional shape is desired. Likewise, the depth of the notches 17 in the photovoltaic cells 12 depends on the radius of curvature of the final curved shape. The notches are produced by any process, such as by laser etching. As a variant, all or some of the notches may even extend through part of the thickness of the flexible substrate.

It will be noted that the flexible substrate 20 ensures good integrity of the entire device after the notches 17 have been produced, even if the latter are great in depth, while limiting the risk of crack propagation. In addition, the flexible substrate 20 provides a second function of electrical continuity, allowing current generated by the various photovoltaic-cell portions to be conducted, even after the notches have been produced, since it is able to conduct electricity between the notched zones and to the other cells.

The result obtained by the steps described above is a photovoltaic device that has a certain relative flexibility that depends on the choice of the network of notches 17, thereby allowing photovoltaic devices in the form of flexible fabrics comprising, for example, a multitude of photovoltaic cells fastened side-by-side on the same flexible substrate to be obtained. Thus, this approach allows an end user to employ the fabric in any application requiring a flexible material, such as for example in the textile industry for an implementation in a piece of clothing.

The manufacturing process may comprise a final step that consists in deforming and shaping the fiat-shaped result, such as shown in FIG. 4, to obtain a final product of three-dimensional shape, such as a cambered tile the shape of which is then set, for example by adding a transparent protective resin 30 to all or part of its surface, to obtain the final product such as shown, by way of example, in FIG. 6. Naturally, this principle may also be used more generally to cover any non-planar surface, such as the surface of an automotive vehicle for example, with photovoltaic devices, The solution is suitable for substantial radii of curvature, radii smaller than or equal to 1 metre for example.

It will be noted that the embodiment was implemented with photovoltaic cells comprising conductors on their back side. As a variant, the same process could be used with cells comprising conductors on their front side or on both their sides. Moreover, the proposed solution allows a final structure (such as shown in FIG. 4) of small thickness to be formed, the thickness of which is smaller than 250 μm, and even smaller than or equal to 200 μm. The one or more photovoltaic cells have a thickness comprised between 50 and 250 μm. The flexible substrate 20 advantageously has a thickness comprised between 100 and 1000 μm.

1. Process for manufacturing a photovoltaic device, wherein it comprises the following steps:
assembling at least one photovoltaic cell to a flexible substrate; then,
producing notches in the at least one photovoltaic cell in order to give it flexibility and allow the photovoltaic device to be deformed.

2. Process for manufacturing a photovoltaic device according to claim 1, wherein it comprises the following initial steps:
producing grooves in the flexible substrate; and
forming electrical conductors in these grooves.

3. Process for manufacturing a photovoltaic device according to claim 2, wherein the electrical conductors are produced in the groove by metal deposition in an electrochemical bath.

4. Process for manufacturing a photovoltaic device according to claim 1, wherein the notches are produced in the at least one photovoltaic cell by laser etching.

5. Process for manufacturing a photovoltaic device according to claim 1, wherein the assembly of at least one photovoltaic cell to a flexible substrate is obtained by polymerisation, cross-linking, welding, or adhesive bonding.

6. Process for manufacturing a photovoltaic device according to claim 1, wherein it comprises an additional step consisting in shaping the photovoltaic device into a non-planar shape.

7. Process for manufacturing photovoltaic device according to claim 1, wherein it comprises an additional step consisting in adding a transparent resin-type protective layer to the photovoltaic device.

8. Photovoltaic device, wherein it comprises at least one photovoltaic cell containing notches, which photovoltaic cell is assembled to a flexible substrate in order to form an assembly that is flexible and/or of non-planar shape.

9. Photovoltaic device according to claim 8, wherein the flexible substrate comprises grooves containing conductors that do not occupy the entire height of the grooves, and wherein the grooves also contain conductors of photovoltaic cells, making contact with the conductors of the flexible substrate.

10. Photovoltaic device according to claim 8, wherein the flexible substrate ensures the mechanical integrity of the entire photovoltaic device, and ensures electrical continuity between the various parts of one or more photovoltaic cells of the photovoltaic device, even with the notches.

11. Photovoltaic device according to claim 9, wherein the flexible substrate comprises a lower layer taking the form of a film and a polymer type resin layer, and in that the grooves extend through all or part of the thickness of the resin layer.

12. Photovoltaic device according to claim 9, wherein the grooves are arranged in such a way as to superpose on the conductors protruding from the surface of the at least one photovoltaic, cell so that these conductors are all housed in the grooves of the flexible substrate.

13. Photovoltaic device according to claim 8, wherein the notches occupy all or part of the thickness of a photovoltaic cell, or the entire thickness of a photovoltaic cell plus part of the thickness of the substrate.

14. Photovoltaic device according to claim 8, wherein the depth of the notches in at least one photovoltaic cell depends on the radius of curvature of the curved shape of the photovoltaic device.

15. Photovoltaic device according to claim 8, wherein the thickness of a photovoltaic cell plus the thickness of the flexible substrate is smaller than or equal to 250 μm, or smaller than or equal to 200 μm, and/or wherein the thickness of a photovoltaic cell is comprised between 50 μm and 250 μm, and/or in that wherein said device comprises at least one photovoltaic cell based silicon and/or wherein the photovoltaic device has a non-planar shape comprising at least one curvature having a radius of curvature smaller than or equal to 1 metre.

16. Device for covering a roof, wherein it comprises an assemblage of photovoltaic devices according to claim 8, taking the form of tiles having a rounded and/or curved and/or cambered surface.

17. Fabric, wherein it comprises photovoltaic devices according to claim 8.

18. Automotive vehicle, wherein it comprises photovoltaic devices according to claim 8 on its surface.
